(19) United States
(12) Patent Application Publication
(10) Pub. No.: US 2021/0189557 A1
(43) Pub. Date: Jun. 24, 2021

(54) SUBSTRATE PROCESSING APPARATUS

(71) Applicant: KOKUSAI ELECTRIC CORPORATION, Tokyo (JP)

(72) Inventors: Hideharu ITATANI, Toyama-shi (JP); Yoshiro HIROSE, Toyama-shi (JP)

(73) Assignee: KOKUSAI ELECTRIC CORPORATION, Tokyo (JP)

(21) Appl. No.: 16/815,557

(22) Filed: Mar. 11, 2020

(30) Foreign Application Priority Data
Dec. 23, 2019 (JP) 2019-231154

(51) Int. Cl. C23C 16/44

(52) U.S. Cl. CPC C23C 16/4412; C23C 16/4405; C23C 16/4408

(57) ABSTRACT

Described herein is a technique capable of suppressing a deposition of reaction by-products in an exhaust pipe. According to one aspect of the technique, there is provided a substrate processing apparatus including: a process chamber where a substrate is processed; a process chamber gas supply system configured to supply a process gas, a purge gas or a cleaning gas into the process chamber; an exhaust pipe configured to perform gas exhaust from the process chamber; an exhaust pipe gas supply system connected to a predetermined deposition risky portion in the exhaust pipe and configured to supply a cleaning contribution gas to the deposition risky portion; and a controller configured to control gas supply through each of the process chamber gas supply system and the exhaust pipe gas supply system.

### CROSS-REFERENCE TO RELATED PATENT APPLICATION

This non-provisional U.S. patent application claims priority under 35 U.S.C. § 119 of Japanese Patent Application No. 2019-231154, filed on Dec. 23, 2019, the entire contents of which are hereby incorporated by reference.

### BACKGROUND

### 1. Field

The present disclosure relates to a substrate processing apparatus.

### 2. Description of the Related Art

A substrate processing apparatus is used to perform a substrate processing which is a part of manufacturing processes of a semiconductor device. For example, the substrate processing apparatus is configured to perform the substrate processing by supplying a process gas to a process chamber where a substrate is accommodated and exhausting the process gas from the process chamber through an exhaust pipe.

However, reaction by-products may be deposited in the exhaust pipe of the substrate processing apparatus. Thereby, a conductance of a gas flow may decrease in the exhaust pipe and a pressure gradient in the process chamber may increase. As a result, a uniformity of the substrate processing of the substrate may be deteriorated.

### SUMMARY

Described herein is a technique capable of suppressing a deposition of reaction by-products in an exhaust pipe.

According to one aspect of the technique of the present disclosure, there is provided a substrate processing apparatus including: a process chamber where a substrate is processed; a process chamber gas supply system configured to supply a process gas, a purge gas or a cleaning gas into the process chamber; an exhaust pipe configured to perform gas exhaust from the process chamber; an exhaust pipe gas supply system connected to a predetermined deposition risky portion in the exhaust pipe and configured to supply a cleaning contribution gas to the deposition risky portion; and a controller configured to control gas supply through each of the process chamber gas supply system and the exhaust pipe gas supply system.

### BRIEF DESCRIPTION OF THE DRAWINGS

FIG. 1 schematically illustrates a single-wafer type substrate processing apparatus according to a first embodiment described herein.

FIG. 2 is a flowchart schematically illustrating a substrate processing according to the first embodiment described herein.

FIG. 3 is a flowchart schematically illustrating a film-forming step of the substrate processing shown in FIG. 2.

FIG. 4 schematically illustrates a single-wafer type substrate processing apparatus according to a third embodiment described herein.

FIG. 5 schematically illustrates a multi-wafer type substrate processing apparatus according to a fourth embodiment described herein.

### DETAILED DESCRIPTION

Hereinafter, embodiments according to the technique of the present disclosure will be described with reference to the drawings.

In the following description, a substrate processing apparatus is an example of an apparatus used to perform a substrate processing in manufacturing processes of a semiconductor device. That is, the substrate processing apparatus is configured to perform a predetermined processing (also referred to as a “substrate processing”) on a substrate to be processed. For example, a silicon wafer (hereinafter, also simply referred to as a “wafer”) serving as a semiconductor substrate on which the semiconductor device is formed may be used as the substrate to be processed. In the present specification, the term “wafer” may refer to “a wafer itself” or may refer to “a wafer and a stacked structure (aggregated structure) of predetermined layers or films formed on a surface of the wafer”. That is, the term “wafer” may collectively refer to “the wafer and the layers or the films formed on the surface of the wafer. In addition, the term “surface of a wafer” may refer to “a surface (exposed surface) of a wafer itself” or may refer to “a surface of a predetermined layer or a film formed on the wafer, i.e. a top surface (uppermost surface) of the wafer as a stacked structure”. In the present specification, the terms “substrate” and “wafer” may be used as substantially the same meaning. For example, as the predetermined processing (substrate processing), a process such as an oxidation process, a diffusion process, an annealing process, an etching process, a pre-cleaning process, a chamber cleaning process and a film-forming process may be performed. Specifically, the embodiments will be described by way of an example in which the film-forming process is performed as the substrate processing.

### First Embodiment

First, a first embodiment according to the technique of the present disclosure will be described in detail.

(1) Configuration of Substrate Processing Apparatus

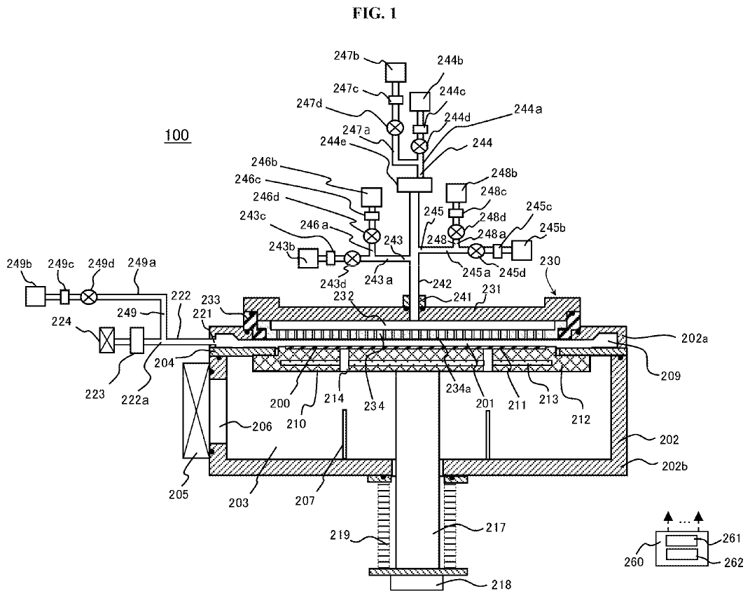

Hereinafter, a configuration of a substrate processing apparatus according to the first embodiment will be described. The first embodiment will be described by way of an example in which a single-wafer type substrate processing apparatus configured to process a wafer to be processed one by one is used as the substrate processing apparatus according to the first embodiment. FIG. 1 schematically illustrates the single-wafer type substrate processing apparatus according to the first embodiment.

<Process Vessel>

As shown in FIG. 1, a substrate processing apparatus 100 according to the first embodiment includes a process vessel 202. For example, the process vessel 202 is a flat and sealed vessel having a circular horizontal cross-section. The process vessel 202 is made of a metal material such as aluminum (Al) and stainless steel (SUS). The process vessel 202 is constituted by an upper vessel 202a and a lower vessel 202b. A partition plate 204 is provided between the upper vessel 202a and the lower vessel 202b.

A process chamber 201 serving as a process space where a wafer 200 is processed and a transfer chamber 203 serving as a transfer space through which the wafer 200 is transferred into or out of the process chamber 201 are provided in the process vessel 202.

An exhaust buffer chamber 209 is provided in the vicinity of an outer peripheral edge inside the upper vessel 202a. The exhaust buffer chamber 209 functions as a buffer space when a gas such as a process gas in the process chamber 201 is exhausted through an outer peripheral portion of the process chamber 201. Therefore, the exhaust buffer chamber 209 includes a space provided so as to surround the outer peripheral portion of the process chamber 201. That is, when viewed from above, the exhaust buffer chamber 209 includes the space of a ring shape (annular shape) on the outer peripheral portion of the process chamber 201.

A substrate loading/unloading port 206 is provided on a side surface of the lower vessel 202b adjacent to a gate valve 205. The wafer 200 is transferred (moved) between a vacuum transfer chamber (not shown) and the transfer chamber 203 through the substrate loading/unloading port 206. Lift pins 207 are provided at a bottom of the lower vessel 202b.

<Substrate Support>

A substrate support 210 capable of supporting the wafer 200 is provided in the process chamber 201. The substrate support 210 mainly includes a substrate support table 212 having a substrate placing surface 211 on which the wafer 200 is placed and a heater 213 serving as a heating source embedded in the substrate support table 212. Through-holes 214 penetrated by the lift pins 207 are provided at the substrate support table 212 corresponding to the locations of the lift pins 207.

The substrate support table 212 is supported by a shaft 217. The shaft 217 penetrates the bottom of the process vessel 202. The shaft 217 is connected to an elevating mechanism 218 outside the process vessel 202. The wafer 200 placed on the substrate placing surface 211 of the substrate support table 212 may be elevated and lowered by operating the elevating mechanism 218 by elevating and lowering the shaft 217 and the substrate support table 212. A bellows 219 covers a lower end portion of the shaft 217 to maintain the process chamber 201 airtight.

When the wafer 200 is transferred, the substrate support table 212 is moved downward until the substrate placing surface 211 faces the substrate loading/unloading port 206 (that is, the substrate support table 212 is moved to a wafer transfer position). When the wafer 200 is processed, the substrate support table 212 is moved upward until the wafer 200 reaches a processing position (also referred to as a “wafer processing position”) in the process chamber 201 as shown in FIG. 1. Specifically, when the substrate support table 212 is lowered to the wafer transfer position, upper end portions of the lift pins 207 protrude from an upper surface of the substrate placing surface 211, and the lift pins 207 support the wafer 200 from thereunder. When the substrate support table 212 is elevated to the wafer processing position, the lift pins 207 are buried from the upper surface of the substrate placing surface 211, and the substrate placing surface 211 supports the wafer 200 from thereunder.

<Shower Head>

A shower head 230 serving as a gas dispersion mechanism is provided at an upper portion of the process chamber 201. That is, the shower head 230 is provided upstream of the process chamber 201 in reference to a gas supply direction. A gas introduction port 241 is provided at a cover 231 of the shower head 230. The gas introduction port 241 is configured to communicate with a gas supply system described later. The gas such as the process gas introduced through the gas introduction port 241 is supplied to a buffer space 232 of the shower head 230.

The cover 231 of the shower head 230 is made of a conductive metal. The cover 231 is used as an electrode configured to generate plasma in the buffer space 232 or in the process chamber 201. An insulating block 233 is provided between the cover 231 and the upper vessel 202a. The insulating block 233 electrically insulates the cover 231 from the upper vessel 202a.

The shower head 230 includes a dispersion plate 234 configured to disperse the gas supplied through the gas supply system via the gas introduction port 241. An upstream side of the dispersion plate 234 is referred to as the buffer space 232, and a downstream side of the dispersion plate 234 is referred to as the process chamber 201. The dispersion plate 234 is provided with a plurality of through-holes 234a. The dispersion plate 234 is arranged to face the substrate placing surface 211.

<Gas Supply System>

A common gas supply pipe 242 is connected to the cover 231 of the shower head 230 so as to communicate with the gas introduction port 241. The common gas supply pipe 242 communicates with the buffer space 232 in the shower head 230 via the gas introduction port 241. In addition, a first gas supply pipe 243a, a second gas supply pipe 244a and a third gas supply pipe 245a are connected to the common gas supply pipe 242. The second gas supply pipe 244a is connected to the common gas supply pipe 242 via a remote plasma mechanism (also referred to as a “remote plasma unit” or simply referred to as an “RPU”) 244e.

A source gas, which is one of process gases, is supplied mainly though a source gas supply system 243. The source gas supply system 243 is a part of the gas supply system, and includes the first gas supply pipe 243a. A reactive gas, which is another of the process gases, is supplied mainly though a reactive gas supply system 244 (hereinafter, the source gas and the reactive gas as the process gases may also be collectively or individually referred to as the “process gas”). The reactive gas supply system 244 is a part of the gas supply system, and includes the second gas supply pipe 244a. When processing the wafer 200, an inert gas serving as a purge gas is mainly supplied though a purge gas supply system 245. The purge gas supply system 245 is a part of the gas supply system, and includes the third gas supply pipe 245a. When cleaning the shower head 230 or the process chamber 201, a cleaning gas is mainly supplied though the purge gas supply system 245. Among the gases supplied through the gas supply system, the source gas may also be referred to as a “first gas”, the reactive gas may also be referred to as a “second gas”, the inert gas may also be referred to as a “third gas”, and the cleaning gas (for the process chamber 201) may also be referred to as a “fourth gas”. The source gas may also be referred to a “first process gas”, and the reactive gas may also be referred to a “second process gas”. In addition, a cleaning contribution gas (for an exhaust pipe 222) supplied through an exhaust pipe cleaning contribution gas supply system described later may be referred to as a “fifth gas”. The exhaust pipe cleaning contribution gas supply system is a part of the gas supply system.

As described above, the first gas supply pipe 243a, the second gas supply pipe 244a and the third gas supply pipe 245a are connected to the common gas supply pipe 242. Thereby, the common gas supply pipe 242 is configured to selectively supply the gases such as the source gas (first gas) or the reactive gas (second gas) serving as the process gas, the inert gas (third gas) serving as the purge gas and the cleaning gas (fourth gas) to the process chamber 201 through the buffer space 232 of the shower head 230. That is, the common gas supply pipe 242 functions as a “first supply pipe” configured to supply the process gas, the purge gas or the cleaning gas to the process chamber 201.

<Source Gas Supply System>

A source gas supply source 243b, a mass flow controller (MFC) 243c serving as a flow rate controller (also referred to as a “flow rate control mechanism”) and a valve 243d serving as an opening/closing valve are provided at the first gas supply pipe 243a in the sequential order from an upstream side to a downstream side of the first gas supply pipe 243a. The source gas is supplied into the shower head 230 via the first gas supply pipe 243a provided with the MFC 243c and the valve 243d and the common gas supply pipe 242.

The source gas (first gas) is one of the process gases. For example, the source gas contains silicon (Si) serving as a first element. Specifically, a gas such as dichlorosilane (SiH₂Cl₂, abbreviated as DCS) gas and tetraethoxysilane (Si(OC₂H₅)₄, abbreviated as TEOS) gas may be used as the source gas. Hereinafter, the first embodiment will be described by way of an example in which the DCS gas is used as the source gas.

The source gas supply system 243 is constituted mainly by the first gas supply pipe 243a, the MFC 243c and the valve 243d. The source gas supply system 243 may further include the source gas supply source 243b and a first inert gas supply system described later. In addition, since the source gas supply system 243 is configured to supply the source gas which is one of the process gases, the source gas supply system 243 is a part of a process gas supply system.

A downstream end of a first inert gas supply pipe 246a is connected to the first gas supply pipe 243a downstream of the valve 243d provided at the first gas supply pipe 243a. An inert gas supply source 246b, an WC 246c and a valve 246d are provided at the first inert gas supply pipe 246a in the sequential order from an upstream side to a downstream side of the first inert gas supply pipe 246a. The inert gas is supplied into the shower head 230 via the first inert gas supply pipe 246a provided with the WC 246c and the valve 246d and the first gas supply pipe 243a.

The inert gas acts as a carrier gas of the source gas. It is preferable that a gas that does not react with the source gas is used as the inert gas. Specifically, for example, nitrogen (N₂) gas may be used as the inert gas. Instead of the N₂ gas, for example, a rare gas such as helium (He) gas, neon (Ne) gas and argon (Ar) gas may be used as the inert gas.

The first inert gas supply system is constituted mainly by the first inert gas supply pipe 246a, the WC 246c and the valve 246d. The first inert gas supply system may further include the inert gas supply source 246b and the first gas supply pipe 243a. As described above, the source gas supply system 243 may further include the first inert gas supply system.

<Reactive Gas Supply System>

A reactive gas supply source 244b, an MFC 244c and a valve 244d are provided at the second gas supply pipe 244a in the sequential order from an upstream side to a downstream side of the second gas supply pipe 244a. The RPU 244e is provided downstream of the valve 244d provided at the second gas supply pipe 244a. The reactive gas is supplied into the shower head 230 via the second gas supply pipe 244a provided with the MFC 244c and the valve 244d and the common gas supply pipe 242. The reactive gas is activated into a plasma state by the RPU 244e and then supplied (irradiated) onto the wafer 200.

The reactive gas (second gas) is another of the process gases. For example, the reactive gas contains a second element (for example, nitrogen) different from the first element (for example, silicon) contained in the source gas. Specifically, for example, ammonia (NH₃) gas serving as a nitrogen (N)-containing gas may be used as the reactive gas.

The reactive gas supply system 244 is constituted mainly by the second gas supply pipe 244a, the MFC 244c and the valve 244d. The reactive gas supply system 244 may further include the reactive gas supply source 244b, the RPU 244e and a second inert gas supply system described later. In addition, since the reactive gas supply system 244 is configured to supply the reactive gas which is another of the process gases, the reactive gas supply system 244 is a part of the process gas supply system.

A downstream end of a second inert gas supply pipe 247a is connected to the second gas supply pipe 244a at a downstream side of the valve 244d provided at the second gas supply pipe 244a. An inert gas supply source 247b, an MFC 247c and a valve 247d are provided at the second inert gas supply pipe 247a in the sequential order from an upstream side to a downstream side of the second inert gas supply pipe 247a. The inert gas is supplied into the shower head 230 via the second inert gas supply pipe 247a provided with the MFC 247c and the valve 247d, the second gas supply pipe 244a and the RPU 244e.

The inert gas acts as a carrier gas or a dilution gas of the reactive gas. Specifically, for example, the nitrogen (N₂) gas may be used as the inert gas. Instead of the N₂ gas, for example, a rare gas such as helium (He) gas, neon (Ne) gas and argon (Ar) gas may be used as the inert gas.

The second inert gas supply system is constituted mainly by the second inert gas supply pipe 247a, the MFC 247c and the valve 247d. The second inert gas supply system may further include the inert gas supply source 247b, the second gas supply pipe 244a and the RPU 244e. As described above, the reactive gas supply system 244 may further include the second inert gas supply system.

<Purge Gas Supply System>

A purge gas supply source 245b, an MFC 245c and a valve 245d are provided at the third gas supply pipe 245a in the sequential order from an upstream side to a downstream side of the third gas supply pipe 245a. When processing the wafer 200 according to a substrate processing described later, the inert gas serving as the purge gas is supplied into the shower head 230 via the third gas supply pipe 245a provided with the MFC 245c and the valve 245d and the common gas supply pipe 242. When cleaning the shower head 230 or the process chamber 201 according to a process space cleaning step described later, the inert gas serving as a carrier gas or a dilution gas of the cleaning gas is supplied into the shower head 230 via the MFC 245c, the valve 245d and the common gas supply pipe 242 as necessary.

The inert gas supplied from the purge gas supply source 245b acts as the purge gas of purging the gas remaining in the process vessel 202 or in the shower head 230 in the substrate processing, and may act as the carrier gas or the dilution gas of the cleaning gas in the process space cleaning step. Specifically, for example, the nitrogen (N₂) gas may be used as the inert gas. Instead of the N₂ gas, for example, a rare gas such as helium (He) gas, neon (Ne) gas and argon (Ar) gas may be used as the inert gas.

The purge gas supply system 245 is constituted mainly by the third gas supply pipe 245a, the MFC 245c and the valve 245d. The purge gas supply system 245 may further include the purge gas supply source 245b and a process space cleaning gas supply system 248 described later.

<Process Space Cleaning Gas Supply System>

A downstream end of a process space cleaning gas supply pipe 248a is connected to the third gas supply pipe 245a at a downstream side of the valve 245d provided at the third gas supply pipe 245a. A process space cleaning gas supply source 248b, an MFC 248c and a valve 248d are provided at the process space cleaning gas supply pipe 248a in the sequential order from an upstream side to a downstream side of the process space cleaning gas supply pipe 248a. In the process space cleaning step, the cleaning gas is supplied into the shower head 230 via the process space cleaning gas supply pipe 248a provided with the MFC 248c and the valve 248d, the third gas supply pipe 245a and the common gas supply pipe 242.

In the process space cleaning step, the cleaning gas (fourth gas) supplied from the process space cleaning gas supply source 248b acts as a cleaning gas of removing substances such as by-products (also referred to as “reaction by-products”) attached to the shower head 230 and the process vessel 202. Specifically, for example, nitrogen trifluoride (NF₃) gas may be used as the cleaning gas. In addition, for example, a gas such as hydrogen fluoride (HF) gas, chlorine trifluoride (ClF₃) gas and fluorine (F₂) gas or a combination thereof may be used as the cleaning gas.

The process space cleaning gas supply system 248 is constituted mainly by the process space cleaning gas supply pipe 248a, the MFC 248c and the valve 248d. The process space cleaning gas supply system 248 may further include the process space cleaning gas supply source 248b and the third gas supply pipe 245a. In addition, the purge gas supply system 245 may further include the process space cleaning gas supply system 248.

While the first embodiment is described by way of an example in which each of the source gas supply system 243, the reactive gas supply system 244, the purge gas supply system 245 and the process space cleaning gas supply system 248 are connected to the process chamber 201 via the common gas supply pipe (first supply pipe) 242, the first embodiment is not limited thereto. For example, the gas supply pipes of the source gas supply system 243, the reactive gas supply system 244, the purge gas supply system 245 and the process space cleaning gas supply system 248 may be directly connected to components such as the shower head 230 and the process chamber 201.

In addition, each of the source gas supply system 243, the reactive gas supply system 244, the purge gas supply system 245 and the process space cleaning gas supply system 248 or a combination thereof may also be referred to as a “process chamber gas supply system”. Then, the process chamber gas supply system functions as a system that supplies the process gas, the purge gas or the cleaning gas to the components such as the shower head 230 and the process chamber 201.

<Gas Exhaust System>

The exhaust pipe 222 is connected to an inside of the exhaust buffer chamber 209 via an exhaust port 221 provided on an upper surface or a side surface of the exhaust buffer chamber 209. Thus, the exhaust pipe 222 communicates with an inside of the process chamber 201 via the exhaust port 221 and the exhaust buffer chamber 209.

An APC (Automatic Pressure Controller) valve 223 serving as a pressure controller is provided at the exhaust pipe 222. The APC valve 223 is configured to adjust (control) an inner pressure of the process chamber 201 communicating with the exhaust buffer chamber 209 to a predetermined pressure. The APC valve 223 includes a valve body (not shown) capable of adjusting the opening degree thereof. The APC valve 223 is configured to adjust a conductance of the exhaust pipe 222 in accordance with an instruction from a controller 260 described later. Hereinafter, the APC valve 223 provided at the exhaust pipe 222 may be simply referred to as the valve 223.

A vacuum pump 224 is provided at the exhaust pipe 222 at a downstream side of the APC valve 223. The vacuum pump 224 is configured to exhaust an inner atmosphere of the exhaust buffer chamber 209 and an inner atmosphere of the process chamber 201 communicating with the exhaust buffer chamber 209 via the exhaust pipe 222. Thus, the exhaust pipe 222 functions as an exhaust pipe configured to exhaust the gas from the process chamber 201.

A gas exhaust system is constituted mainly by the exhaust pipe 222, the APC valve 223 and the vacuum pump 224.

<Exhaust Pipe Cleaning Contribution Gas Supply System>

Separately from the process space cleaning gas supply system 248, the exhaust pipe cleaning contribution gas supply system (hereinafter, also simply referred to as “exhaust pipe gas supply system”) 249 serving as a part of the gas supply system is connected to the exhaust pipe 222 constituting the gas exhaust system.

The exhaust pipe gas supply system 249 includes an exhaust pipe cleaning contribution gas supply pipe (hereinafter, also simply referred to as an “exhaust pipe gas supply pipe”) 249a directly communicating with the exhaust pipe 222. The exhaust pipe gas supply pipe 249a is provided separately from the common gas supply pipe (first supply pipe) 242. Therefore, hereinafter, the exhaust pipe gas supply pipe 249a may also be referred to as a “second supply pipe”.

The exhaust pipe gas supply pipe (second supply pipe) 249a is connected to a predetermined deposition risky portion 222a in the exhaust pipe 222. In the present specification, the term “deposition risky portion” refers to a portion where unwanted reactants (also referred to as “unnecessary reactants”) such as the by-products are likely to be deposited. According to the first embodiment, the deposition risky portion 222a is located in the exhaust pipe 222 between the exhaust port 221 and the APC valve 223. That is, according to the first embodiment, the deposition risky portion 222a is determined such that a connection location of the exhaust pipe gas supply pipe 249a connected to the exhaust pipe 222 is located between the exhaust port 221 and the APC valve 223. As described above, the exhaust pipe 222 is configured to communicate with the inside of the process chamber 201 via the exhaust port 221, and the APC valve 223 is provided at the exhaust pipe 222. Therefore, the deposition risky portion 222a may be located between the process chamber 201 and the APC valve 223.

An exhaust pipe cleaning contribution gas supply source (hereinafter, also simply referred to as an “exhaust pipe gas supply source”) 249b, an WC 249c and a valve 249d are provided at the exhaust pipe gas supply pipe 249a in the sequential order from an upstream side to a downstream side of the exhaust pipe gas supply pipe 249a. The cleaning contribution gas is supplied into the exhaust pipe 222 via the exhaust pipe gas supply pipe 249a provided with the MFC 249c and the valve 249d.

In the present specification, the term “cleaning contribution gas” refers to a gas contributing to a cleaning process of removing the substances such as the by-products attached to the exhaust pipe 222. Specifically, for example, a cleaning gas of removing the substances such as the by-products or a cleaning auxiliary gas of activating the cleaning gas may be referred to as the cleaning contribution gas described herein. According to the first embodiment, the cleaning gas may be used as the cleaning contribution gas. For example, a fluorine-containing gas such as NF₃ gas, F₂ gas, HF gas and ClF₃ gas may be used as the cleaning gas (that is, the cleaning contribution gas).

The exhaust pipe gas supply system 249 is constituted mainly by the exhaust pipe gas supply pipe 249a, the MFC 249c and the valve 249d. The exhaust pipe gas supply system 249 may further include the exhaust pipe gas supply source 249b.

<Controller>

The substrate processing apparatus 100 includes the controller 260 configured to control operations of the components of the substrate processing apparatus 100. The controller 260 includes at least an arithmetic unit 261 and a memory device 262. The controller 260 is connected to the components of the substrate processing apparatus 100 described above, calls a program or a recipe from the memory device 262 in accordance with an instruction from a host controller or a user, and controls the operations of the components of the substrate processing apparatus 100 according to the contents of the instruction. Specifically, the controller 260 may be configured to control the operations of the components such as the gate valve 205, the elevating mechanism 218, the heater 213, the MFCs 243c through 248c, the valves 243d through 248d, the MFC 249c, the valve 249d, the APC valve 223 and the vacuum pump 224. That is, control targets of the controller 260 may include at least a gas supply through the process chamber gas supply system and a gas supply through the exhaust pipe gas supply system 249.

The controller 260 may be embodied by a dedicated computer or by a general-purpose computer. For example, the controller 260 may be embodied by preparing an external memory device storing the program described above and by installing the program onto the general-purpose computer using the external memory device. For example, the external memory device may include a magnetic tape, a magnetic disk such as a flexible disk and a hard disk, an optical disk such as a CD and a DVD, a magneto-optical disk such as an MO and a semiconductor memory such as a USB memory and a memory card.

The means for providing the program to the computer is not limited to the external memory device. For example, the program may be supplied to the computer (general-purpose computer) using communication means such as the Internet and a dedicated line. In addition, the memory device 262 or the external memory device may be embodied by a non-transitory computer readable recording medium. Hereafter, the memory device 262 and the external memory device may be collectively referred to as the recording medium. In the present specification, the term “recording medium” may refer to only the memory device 262, may refer to only the external memory device or may refer to both of the memory device 262 and the external memory device.

(2) Substrate Processing

Subsequently, the substrate processing of processing the wafer 200, which is a part of the manufacturing processes of the semiconductor device, will be described. The substrate processing is performed by using the above-described substrate processing apparatus 100. Hereinafter, the substrate processing will be described by way of an example in which a film is formed on the wafer 200. In particular, the substrate processing of the first embodiment will be described by way of an example in which a silicon nitride film (also simply referred to as an “SiN film”) serving as a silicon-containing film is formed on the wafer 200 by alternately supplying the DCS gas and the NH₃ gas onto the wafer 200. That is, the DCS gas is used as the source gas (first gas), and the NH₃ gas is used as the reactive gas (second gas). In the following descriptions, in the substrate processing, the operations of the components of the substrate processing apparatus 100 are controlled by the controller 260.

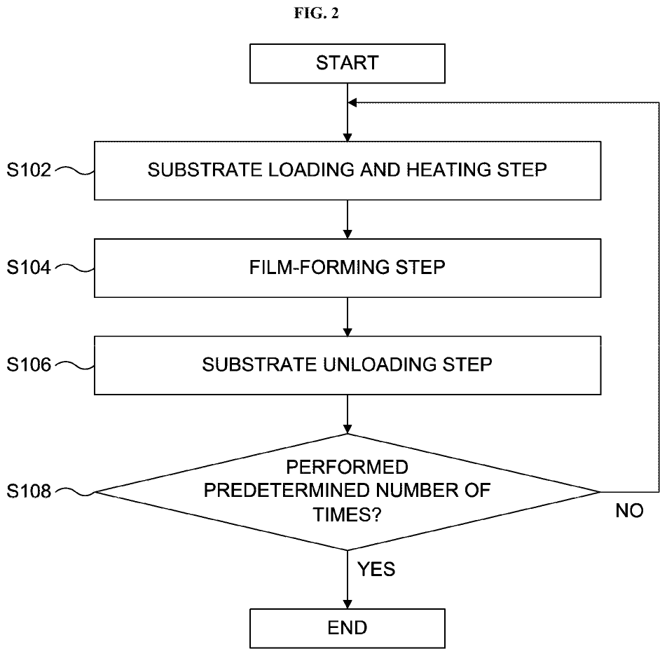

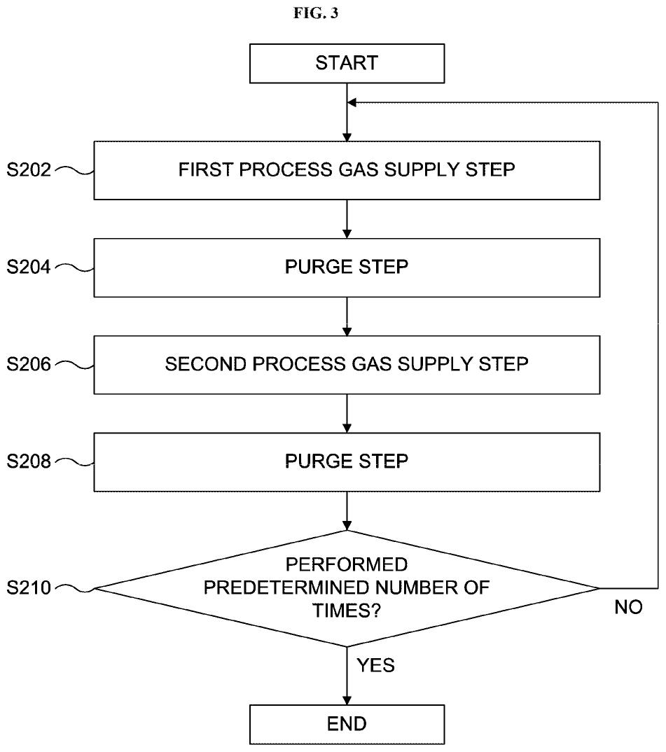

FIG. 2 is a flowchart schematically illustrating the substrate processing according to the first embodiment. FIG. 3 is a flowchart schematically illustrating a film-forming step of the substrate processing shown in FIG. 2.

<Substrate Loading and Heating Step S102>

When the substrate processing is performed by using the substrate processing apparatus 100, first, as shown in FIG. 2, a substrate loading and heating step S102 is performed. In the substrate loading and heating step S102, the wafer 200 is transferred (loaded) into the process vessel 202. After the wafer 200 is loaded into the process vessel 202, a vacuum transfer robot (not shown) is retracted to an outside of the process vessel 202, and the gate valve 205 is closed to seal the process vessel 202 hermetically. Thereafter, by elevating the substrate support table 212, the wafer 200 is placed on the substrate placing surface 211 of the substrate support table 212. By further elevating the substrate support table 212, the wafer 200 is elevated to the position for processing the wafer 200 (that is, the wafer processing position) in the process chamber 201.

After the wafer 200 is loaded into the transfer chamber 203 and elevated to the wafer processing position in the process chamber 201, by operating (opening) the APC valve 223, the exhaust buffer chamber 209 communicates with the vacuum pump 224 via the APC valve 223. The APC valve 223 controls an exhaust flow rate of the exhaust buffer chamber 209 by the vacuum pump 224 by adjusting the conductance of the exhaust pipe 222. The inner pressure of the process chamber 201 communicating with the exhaust buffer chamber 209 is thereby maintained at a predetermined processing pressure.

When the wafer 200 is placed on the substrate support table 212, the electric power is supplied to the heater 213 embedded in the substrate support table 212 such that a temperature (surface temperature) of the wafer 200 is adjusted to a predetermined processing temperature. In the substrate loading and heating step S102, a temperature of the heater 213 is adjusted by controlling a state of electric conduction to the heater 213 based on temperature information detected by a temperature sensor (not shown).

In the substrate loading and heating step S102, the inner pressure of the process chamber 201 is adjusted to the predetermined processing pressure and the surface temperature of the wafer 200 is adjusted to the predetermined processing temperature. In the present specification, the predetermined processing temperature and the predetermined processing pressure refer to a processing temperature and a processing pressure, respectively, at which the SiN film can be formed by alternately supplying the DCS gas and the NH₃ gas onto the wafer 200 in a film-forming step S104 described later. That is, the predetermined processing temperature and the predetermined processing pressure refer to the processing temperature and the processing pressure, respectively, at which the source gas supplied in a first process gas supply step (also be referred to as a “source gas supply step”) S202 described later cannot be self-decomposed. Specifically, for example, the processing temperature may range from the room temperature to 500° C., preferably from the room temperature to 400° C. For example, the processing pressure may range from 50 Pa to 5,000 Pa. The processing temperature and the processing pressure are also maintained in the film-forming step S104 described later.

<Film-Forming Step S104>

After the substrate loading and heating step S102, the film-forming step S104 is performed. Hereinafter, the film-forming step S104 will be described in detail with reference to

FIG. 3. As the film-forming step S104, a cyclic process may be performed by repeating alternately supplying different process gases (that is, by repeatedly and alternately performing the first process gas supply step S202 and a second process gas supply step S206 described later).

<First Process Gas Supply Step S202>

In the film-forming step S104, first, the first process gas supply step (source gas supply step) S202 is performed. In the first process gas supply step S202, the DCS gas serving as the source gas (first gas) is supplied into the process chamber 201 through the source gas supply system 243. The DCS gas supplied into the process chamber 201 is then supplied onto a surface of the wafer 200 at the wafer processing position. By the DCS gas contacting the surface of the wafer 200, a silicon-containing layer serving as a first element-containing layer is formed on the surface of the wafer 200. For example, the silicon-containing layer having a predetermined thickness and a predetermined distribution is formed according to the conditions such as an inner pressure of the process vessel 202 (that is, the inner pressure of the process chamber 201), a flow rate of the DCS gas supplied into the process chamber 201, a temperature of the substrate support table 212 and the time taken for the DCS gas to pass through the process chamber 201.

After a predetermined time elapses from the supply of the DCS gas, the valve 243d is closed to stop the supply of the DCS gas. In the first process gas supply step S202, the inner pressure of the process chamber 201 is controlled (adjusted) by the APC valve 223 to the predetermined processing pressure.

<Purge Step S204>

After the first process gas supply step S202, a purge step S204 is performed. In the purge step S204, the N₂ gas is supplied through the purge gas supply system 245 to purge the process chamber 201 and the shower head 230. As a result, the DCS gas that could not be bonded to the wafer 200 in the first process gas supply step S202 is removed from the process chamber 201 by the vacuum pump 224.

<Second Process Gas Supply Step S206>

After the purge step S204, the NH₃ gas serving as the reactive gas (second gas) is supplied into the process chamber 201 through the reactive gas supply system 244. The NH₃ gas may be activated into the plasma state by the RPU 244e and then irradiated onto the surface of the wafer 200 at the wafer processing position. By supplying the NH₃ gas into the process chamber 201, the silicon-containing layer formed on the surface of the wafer 200 is modified (changed) to form, for example, the SiN film which is a layer containing silicon (Si) and nitrogen (O).

After a predetermined time elapses from the supply of the NH₃ gas, the valve 244d is closed to stop the supply of the NH₃ gas. Similar to the first process gas supply step S202, the inner pressure of the process chamber 201 in the second process gas supply step S206 is controlled (adjusted) by the APC valve 223 to the predetermined processing pressure.

<Purge Step S208>

After the second process gas supply step S206, a purge step S208 is performed. The operations of the components of the substrate processing apparatus 100 in the purge step S208 is similar to those of the components in the purge step S204. Therefore, the detailed descriptions of the purge step S208 are omitted.

<Determination Step S210>

Hereinafter, a determination step S210 will be described. After the purge step S208 is completed, in the determination step S210, the controller 260 determines whether a cycle including the first process gas supply step S202 through the purge step S208 has been performed a predetermined number of times (n times). When the controller 260 determines, in the determination step S210, that the cycle has not been performed the predetermined number of times (n times) (“NO” in FIG. 3), the first process gas supply step S202 through the purge step S208 are performed again. When the controller 260 determines, in the determination step S210, that the cycle has been performed the predetermined number of times (n times) (“YES” in FIG. 3), the film-forming step S104 is terminated.

As described above, in the film-forming step S104, by sequentially performing the first process gas supply step S202 through the purge step S208, the SiN film having a predetermined thickness is deposited on the surface of the wafer 200. By performing the cycle including the first process gas supply step S202 through the purge step S208 a predetermined number of times, it is possible to control the thickness of the SiN film formed on the surface of the wafer 200 to a desired thickness.

<Substrate Unloading Step S106>

After the film-forming step 5104 is completed, as shown in FIG. 2, a substrate unloading step 5106 is performed by the substrate processing apparatus 100. In the substrate unloading step S106, the processed wafer 200 is transferred (unloaded) out of the process vessel 202 in the order reverse to that of the substrate loading and heating step 5102. Subsequent to a determination step S108 described later, an unprocessed wafer 200 may be loaded into the process vessel 202 in the order same as that of the substrate loading and heating step 5102. The loaded wafer 200 will be subject to the film-forming step S104 thereafter.

<Determination Step S108>

After the substrate unloading step 5106 is completed, in the determination step 5108, the controller 260 of the substrate processing apparatus 100 determines whether a cycle including the substrate loading and heating step 5102, the film-forming step 5104 and the substrate unloading step S106 has been performed a predetermined number of times. That is, the controller 260 determines whether the number of wafers including the wafer 200 processed in the film-forming step S104 is equal to the predetermined number. When it is determined, in the determination step S108, that the cycle has not been performed the predetermined number of times (“NO” in FIG. 2), the substrate loading and heating step S102, the film-forming step S104 and the substrate unloading 5106 are performed again to process the unprocessed wafer 200. When it is determined, in the determination step S108, that the cycle has been performed the predetermined number of times (“YES” in FIG. 2), the substrate processing is terminated.

When the substrate processing is completed, no wafer remains in the process vessel 202.

(3) Cleaning Step of Process Chamber

Subsequently, a cleaning step (also referred to as the “process space cleaning step”) of performing a cleaning process to the inside of the process chamber 201 of the substrate processing apparatus 100, which is a part of the manufacturing processes of the semiconductor device, will be described.

When the substrate processing described above is repeatedly performed, the unnecessary reactants such as the by-products may be attached to a surface of a wall in the process vessel 202 (particularly, in the process chamber 201). Therefore, the substrate processing apparatus 100 performs the cleaning step of the process chamber 201 (that is, the process space cleaning step) at a predetermined timing (for example, after performing the substrate processing a predetermined number of times, after processing a predetermined number of wafers including the wafer 200 or after a predetermined time has elapsed from the previous cleaning process).

In the cleaning step of the process chamber 201, the valve 248d is opened while the valves 243d, 244d, 245d, 246d, 247d and 249d are closed. Thereby, the cleaning gas is supplied into the process chamber 201 from the process space cleaning gas supply source 248b of the process space cleaning gas supply system 248 via the third gas supply pipe 245a and the common gas supply pipe 242. Then, the cleaning gas supplied into the process chamber 201 removes attached substances such as the reaction by-products in the buffer space 232 and in the process chamber 201.

As a result, for example, even when the substances such as the by-products attached to the surface of the wall in the process chamber 201, it is possible to remove the substances such as the by-products by performing the cleaning step of the process chamber 201 at the predetermined timing.

(4) Cleaning Step of Exhaust Pipe

Subsequently, a cleaning step (also referred to as the “exhaust pipe cleaning step”) of performing a cleaning process to an inside of the exhaust pipe 222 of the substrate processing apparatus 100, which is a part of the manufacturing processes of the semiconductor device, will be described.

When the substrate processing described above is repeatedly performed, the unnecessary reactants such as the by-products may be attached to not only the inside of the process chamber 201 but also the inside of the exhaust pipe 222 configured to exhaust the gas from the process chamber 201. In particular, the unnecessary reactants such as the by-products may easily be attached to and be deposited on the deposition risky portion 222a of the exhaust pipe 222. As described above, the deposition risky portion 222a is located between the exhaust port 221 and the APC valve 223. Hereinafter, the reason will be briefly described.

The APC valve 223 is configured to adjust a pressure such as the inner pressure of the process chamber 201 and an inner pressure of the exhaust pipe 222 (particularly, a pressure of a portion between the exhaust port 221 and the APC valve 223 in the exhaust pipe 222). For example, the APC valve 223 adjusts the inner pressure of the process chamber 201 to the predetermined processing pressure when the substrate processing is performed. The heater 213 heats the inside of process chamber 201 to the predetermined processing temperature when the substrate processing is performed. Since an O-ring (not shown) having a low heat resistance is disposed as a sealing part between the exhaust pipe 222 and the process vessel 202, the exhaust pipe 222 is configured not to be affected by the heat from the heater 213. In addition, when the substrate processing is performed, the inner pressure of the exhaust pipe 222 becomes high because the gas flows from the process chamber 201, which is wider, into the pipe (that is, the exhaust pipe 222), which is narrower. As described above, since the pressure is high and the temperature is low in the exhaust pipe 222, particularly in a portion such as the deposition risky portion 222a between the exhaust port 221 and the APC valve 223, the substances such as the by-products may easily be attached to and be deposited on the portion.

Therefore, according to the first embodiment, after the cleaning step of the process chamber 201 is performed, subsequently, the cleaning step of the exhaust pipe 222 is performed.

According to the cleaning step of the exhaust pipe 222, after stopping the supply of the cleaning gas through the common gas supply pipe 242, which has been performed in the cleaning step of the process chamber 201, the supply of the purge gas through the common gas supply pipe 242 is started. More specifically, by closing the valve 248d and opening the valve 245d, the purge gas is supplied into the process chamber 201 from the purge gas supply source 245b through the third gas supply pipe 245a and the common gas supply pipe 242.

Thereafter, in the cleaning step of the exhaust pipe 222, the valve 249d is opened. Thereby, the cleaning gas serving as the cleaning contribution gas is supplied to the deposition risky portion 222a in the exhaust pipe 222 (that is, the portion between the exhaust port 221 and the APC valve 223) from the exhaust pipe gas supply source 249b through the exhaust pipe gas supply pipe 249a. That is, in parallel with supplying the purge gas through the common gas supply pipe 242 to the process chamber 201, the cleaning gas is supplied to the deposition risky portion 222a in the exhaust pipe 222 through the exhaust pipe gas supply pipe 249a. As a result, the cleaning gas supplied to the deposition risky portion 222a removes the attached substances such as the reaction by-products at the deposition risky portion 222a.

In the cleaning step of the exhaust pipe 222, the purge gas is supplied into the process chamber 201. Therefore, even when the cleaning gas is supplied directly into the exhaust pipe 222, it is possible to suppress the cleaning gas from entering the process chamber 201. That is, the purge gas supplied into the process chamber 201 prevents the cleaning gas supplied into the exhaust pipe 222 from entering the process chamber 201. In addition, by supplying the purge gas into the process chamber 201 before starting the supply of the cleaning gas into the exhaust pipe 222, it is possible to reliably prevent the cleaning gas from entering the process chamber 201.

(5) Effects According to First Embodiment

According to the first embodiment described above, it is possible to provide one or more of the following effects.

(a) According to the first embodiment, the exhaust pipe gas supply pipe 249a is connected to the deposition risky portion 222a in the exhaust pipe 222. Therefore, even when the substances such as the by-products are easily attached to and deposited on the deposition risky portion 222a, it is possible to remove the attached substances such as the reaction by-products at the deposition risky portion 222a by supplying the cleaning contribution gas to the deposition risky portion 222a.

As described above, according to the first embodiment, it is possible to suppress the deposition of the reaction by-products not only in the process chamber 201 but also in the exhaust pipe 222. Therefore, it is possible to suppress a decrease in a conductance of a gas flow due to the deposition of the reaction by-products in the exhaust pipe 222. In addition, it is possible to prevent an increase in pressure gradient in the process chamber 201 due to the decrease in the conductance. As a result, it is possible to prevent a processing uniformity of the wafer 200 from deteriorating.

(b) According to the first embodiment, the deposition risky portion 222a in the exhaust pipe 222 is located between the exhaust port 221 and the APC valve 223. As described above, the exhaust pipe 222 is configured to communicate with the inside of the process chamber 201 via the exhaust port 221, and the APC valve 223 is provided at the exhaust pipe 222. Since the pressure of the portion between the exhaust port 221 and the APC valve 223 is high and the temperature of the portion is low, the substances such as the by-products may easily be attached to and be deposited on the portion. Particularly, the exhaust pipe gas supply pipe 249a is connected to the portion where the reaction by-products are likely to be deposited. Therefore, it is possible to more effectively and efficiently suppress the deposition of the reaction by-products in the exhaust pipe 222.

(c) According to the first embodiment, the cleaning gas serving as the cleaning contribution gas is supplied through the exhaust pipe gas supply system 249. That is, the cleaning gas that directly contributes to the removal of the substances such as the by-products attached to the exhaust pipe 222 is supplied as the cleaning contribution gas. Therefore, by using the cleaning gas serving as the cleaning contribution gas, it is possible to more efficiently and reliably remove the substances such as the reaction by-products deposited on the exhaust pipe 222.

(d) According to the first embodiment, when the gas is supplied through the exhaust pipe gas supply pipe 249a into the exhaust pipe 222, the purge gas is supplied through the common gas supply pipe 242 into the process chamber 201. Therefore, even when the cleaning gas is supplied directly into the exhaust pipe 222, by supplying the purge gas, it is possible to suppress the cleaning gas from entering the process chamber 201. In addition, by supplying the purge gas into the process chamber 201 before starting the supply of the cleaning gas into the exhaust pipe 222, it is possible to reliably prevent the cleaning gas from entering the process chamber 201.

### Second Embodiment

Hereinafter, a second embodiment according to the technique of the present disclosure will be described in detail. In the second embodiment, only portions different from those of the first embodiment will be described in detail below, and the description of portions the same as the first embodiment will be omitted.

In the second embodiment, a configuration of the exhaust pipe gas supply system 249 and a cleaning step of the exhaust pipe 222 using the exhaust pipe gas supply system 249 according to the second embodiment are different from those of the first embodiment.

According to the second embodiment, the cleaning auxiliary gas serving as the cleaning contribution gas is supplied from the exhaust pipe gas supply source 249b of the exhaust pipe gas supply system 249. When the fluorine-containing gas such as NF₃ gas and F₂ gas is supplied as the cleaning gas into the process chamber 201, an oxygen-containing gas such as nitric oxide (NO) gas and oxygen (O₂) gas of activating the cleaning gas may be used as the cleaning auxiliary gas. In addition, the exhaust pipe gas supply system 249 may be configured to supply the cleaning gas in addition to the cleaning auxiliary gas.

Subsequently, the cleaning step of the exhaust pipe 222 using the exhaust pipe gas supply system 249 according to the second embodiment will be described.

In the cleaning step of the process chamber 201, the cleaning gas is supplied into the process chamber 201 through the common gas supply pipe 242. Then, the cleaning gas supplied into the process chamber 201 is exhausted out of the process vessel 202 through the exhaust buffer chamber 209 and the exhaust pipe 222.

When the cleaning gas is exhausted through the exhaust buffer chamber 209 and the exhaust pipe 222, the energy of the cleaning gas may be deactivated by the time it reaches the exhaust pipe 222. In particular, since the inner pressure of the exhaust pipe 222 is higher than the inner pressure of the process chamber 201, a kinetic efficiency of the cleaning gas is further reduced, and a cleaning effect by the cleaning gas is also reduced.

Therefore, according to the second embodiment, the cleaning step of the exhaust pipe 222 is performed in parallel with the cleaning step of the process chamber 201.

In the cleaning step of the exhaust pipe 222, by opening the valve 249d, the cleaning auxiliary gas serving as the cleaning contribution gas is supplied to the deposition risky portion 222a in the exhaust pipe 222 (that is, the portion between the exhaust port 221 and the APC valve 223) from the exhaust pipe gas supply source 249b through the exhaust pipe gas supply pipe 249a. That is, in parallel with supplying the cleaning gas through the common gas supply pipe 242 to the process chamber 201, the cleaning auxiliary gas is supplied to the deposition risky portion 222a in the exhaust pipe 222 through the exhaust pipe gas supply pipe 249a.

As a result, the cleaning gas, supplied through the common gas supply pipe 242 and having reached the deposition risky portion 222a in the exhaust pipe 222 via the process chamber 201, is activated by the cleaning auxiliary gas supplied to the deposition risky portion 222a. Then, the cleaning gas activated by the cleaning auxiliary gas removes the attached substances such as the reaction by-products at the deposition risky portion 222a in the exhaust pipe 222 while an energy efficiency of the cleaning gas is increased and a cleaning ability of the cleaning gas in the exhaust pipe 222 is enhanced.

In the cleaning step of the exhaust pipe 222, the cleaning gas, in addition to the cleaning auxiliary gas, may be simultaneously supplied through the exhaust pipe gas supply pipe 249a. When the cleaning gas is simultaneously supplied with the cleaning auxiliary gas through the exhaust pipe gas supply pipe 249a, a concentration of the cleaning gas is increased. As a result, it is possible to further enhance the cleaning ability of the cleaning gas in the exhaust pipe 222.

According to the second embodiment described above, it is possible to provide one or more of the following effects in addition to the effects (a) through (d) of the first embodiment described above.

(e) According to the second embodiment, the cleaning auxiliary gas serving as the cleaning contribution gas is supplied through the exhaust pipe gas supply system 249 in parallel with supplying the cleaning gas through the common gas supply pipe 242 into the process chamber 201. That is, by supplying the cleaning auxiliary gas, it is possible to activate the cleaning gas that has reached the deposition risky portion 222a in the exhaust pipe 222. Therefore, the cleaning ability of the cleaning gas is enhanced by activating the cleaning gas. As a result, it is possible to more efficiently and reliably remove the substances such as the reaction by-products deposited on the exhaust pipe 222.

(f) According to the second embodiment, the cleaning auxiliary gas is used as the cleaning contribution gas. Thus, it is possible to perform the cleaning step of the process chamber 201 in parallel with the cleaning step of the exhaust pipe 222. Therefore, according to the second embodiment, it is possible to reduce the time required for the cleaning steps described above as compared with a case where each of the cleaning steps described above is performed separately. As a result, it is also possible to improve an operation rate of the substrate processing apparatus 100.

### Third Embodiment

Hereinafter, a third embodiment according to the technique of the present disclosure will be described. In the third embodiment, only portions different from those of the first embodiment or the second embodiment will be described in detail below, and the description of portions the same as the first embodiment or the second embodiment will be omitted.

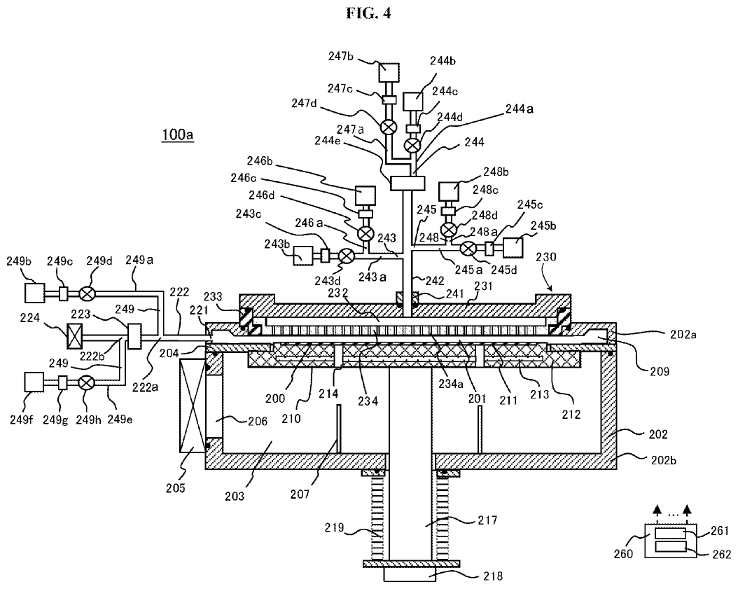

In the third embodiment, a configuration of the exhaust pipe gas supply system 249 and a cleaning step of the exhaust pipe 222 using the exhaust pipe gas supply system 249 are different from those of the first embodiment. FIG. 4 schematically illustrates a single-wafer type substrate processing apparatus (that is, a substrate processing apparatus 100a) according to the third embodiment.

As shown in FIG. 4, according to the substrate processing apparatus 100a of the third embodiment, the exhaust pipe gas supply system 249 further includes an exhaust pipe gas supply pipe (also referred to as a “third supply pipe”) 249e in addition to the exhaust pipe gas supply pipe 249a, the exhaust pipe gas supply source 249b, the MFC 249c and the valve 249d described in the first embodiment. The exhaust pipe gas supply pipe 249e directly communicates with the exhaust pipe 222. An exhaust pipe gas supply source 249f, an MFC 249g and a valve 249h are provided at the exhaust pipe gas supply pipe 249e in the sequential order from an upstream side to a downstream side of the exhaust pipe gas supply pipe 249e. The cleaning contribution gas is supplied into the exhaust pipe 222 via the exhaust pipe gas supply pipe 249e provided with the MFC 249g and the valve 249h.

The exhaust pipe gas supply pipe (third supply pipe) 249e is connected to a deposition risky portion 222b different from the deposition risky portion 222a of the exhaust pipe gas supply pipe 249a. The deposition risky portion 222b is located downstream of the APC valve 223 provided at the exhaust pipe 222. More specifically, at the downstream side of the APC valve 223, the deposition risky portion 222b is located immediately after the APC valve 223. That is, according to the third embodiment, the deposition risky portion 222b is set such that a connection location of the exhaust pipe gas supply pipe 249e connected to the exhaust pipe 222 is located at the downstream of the APC valve 223 immediately after the APC valve 223. In the present specification, the term “immediately after the APC valve 223” refers to a range of region where the APC valve 223 is not far away and a partial pressure and a temperature can be reduced as described later in detail.

Similar to the first embodiment, for example, the cleaning gas is used as the cleaning contribution gas supplied to the deposition risky portion 222b through the exhaust pipe gas supply pipe 249e. However, the third embodiment is not limited thereto. For example, similar to the second embodiment, the cleaning auxiliary gas may be used as the cleaning contribution gas.

Subsequently, the cleaning step of the exhaust pipe 222 performed using the exhaust pipe gas supply system 249 according to the third embodiment will be described. In the third embodiment, the cleaning step of the exhaust pipe 222 will be described by way of an example in which the cleaning gas is used as the cleaning contribution gas.

Similar to the first embodiment, after the cleaning step of the process chamber 201 is performed, the cleaning process of the cleaning step of the exhaust pipe 222 is performed by supplying the cleaning gas to the deposition risky portion 222a in the exhaust pipe 222 (that is, the portion between the exhaust port 221 and the APC valve 223) through the exhaust pipe gas supply pipe 249e.

Thereafter, when the cleaning process for the deposition risky portion 222a is completed, the APC valve 223 is closed and the valve 249h is opened. Thereby, the cleaning gas serving as the cleaning contribution gas is supplied from the exhaust pipe gas supply source (also referred to as an “exhaust pipe cleaning contribution gas supply source”) 249f to the deposition risky portion 222b (that is, the portion immediately after the downstream side of the APC valve 223) of the exhaust pipe 222 different from the deposition risky portion 222a.

By the influence of the vacuum pump 224, the partial pressure and the temperature of the portion immediately after the APC valve 223 (that is, the range of the region described above) are reduced simultaneously. Therefore, the substances such as the by-products may easily be attached to and be deposited on the portion.

Therefore, according to the third embodiment, the range of the region described above is defined as the deposition risky portion 222b. By supplying the cleaning gas to the portion immediately after the downstream side of the APC valve 223, it is possible to remove the attached substances such as the reaction by-products at the deposition risky portion 222b.

While the third embodiment is described by way of an example in which the cleaning gas is supplied in order to remove the substances such as the by-products at the portion immediately after the downstream side of the APC valve 223, the third embodiment is not limited thereto. For example, similar to the second embodiment, the cleaning auxiliary gas may be used.

While the third embodiment is described by way of an example in which the cleaning step of the exhaust pipe 222 includes the cleaning process of cleaning the deposition risky portion 222a (that is, the portion between the exhaust port 221 and the APC valve 223) and the cleaning process of cleaning the deposition risky portion 222b (that is, the portion immediately after the downstream side of the APC valve 223) performed after the cleaning process of cleaning the deposition risky portion 222a, the third embodiment is not limited thereto. For example, the cleaning step of the exhaust pipe 222 may include only the cleaning process of cleaning the portion immediately after the downstream side of the APC valve 223. That is, in the exhaust pipe gas supply system 249, only the exhaust pipe gas supply pipe 249e may be connected to the exhaust pipe 222, and only the portion immediately after the downstream side of the APC valve 223 may be defined as the deposition risk location 222b.

According to the third embodiment described above, it is possible to provide the following effect in addition to the effects (a) through (f) of the first embodiment or the second embodiment described above.

(g) According to the third embodiment, the deposition risky portion 222b of the exhaust pipe 222 is located downstream of the APC valve 223 provided at the exhaust pipe 222. The partial pressure and the temperature of the portion downstream of the APC valve 223 (that is, the portion immediately after the APC valve 223) are reduced simultaneously. Particularly, the exhaust pipe gas supply pipe 249e is connected to the portion where the reaction by-products are likely to be deposited. Therefore, it is possible to more effectively and efficiently suppress the deposition of the reaction by-products in the exhaust pipe 222.

### Fourth Embodiment

Hereinafter, a fourth embodiment according to the technique of the present disclosure will be described. In the fourth embodiment, only portions different from those of the first embodiment or the second embodiment will be described in detail below, and the description of portions the same as the first embodiment or the second embodiment will be omitted.

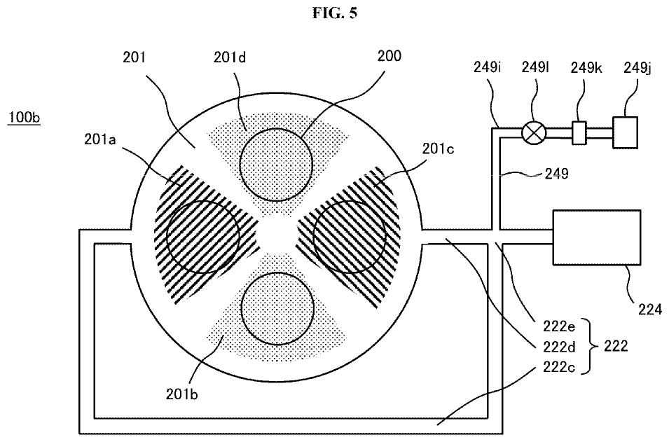

FIG. 5 schematically illustrates a multi-wafer type substrate processing apparatus (that is, a substrate processing apparatus 100b) according to the fourth embodiment.

As shown in FIG. 5, a source gas supply region 201a, a purge gas supply region 201b, a reactive gas supply region 201c and a purge gas supply region 201d are arranged in the process chamber 201 of the substrate processing apparatus 100b of the fourth embodiment. The source gas (first gas), which is one of the process gases, is supplied to the source gas supply region 201a. The purge gas is supplied to the purge gas supply region 20 lb. The reactive gas, which is another of the process gases, is supplied to the reactive gas supply region 201c. The purge gas is also supplied to the purge gas supply region 201d. As the wafer 200 sequentially passes through the regions 201a to 201d by rotating a substrate support table on which wafers including the wafer 200 are placed, a film-forming process according to the fourth embodiment is performed onto the wafer 200.

In the vicinity of the source gas supply region 201a in the process chamber 201, a source gas exhaust pipe portion 222c is connected. The source gas exhausted from the process chamber 201 flows through the source gas exhaust pipe portion 222c. In the vicinity of the reactive gas supply region 201c in the process chamber 201, a reactive gas exhaust pipe portion 222d is connected. The reactive gas exhausted from the process chamber 201 flows through the reactive gas exhaust pipe portion 222d. The source gas exhaust pipe portion 222c and the reactive gas exhaust pipe portion 222d join (merge) at a confluent portion (also referred to as a “junction”) 222e located downstream of each of the source gas exhaust pipe portion 222c and the reactive gas exhaust pipe portion 222d. That is, according to the substrate processing apparatus 100b of the fourth embodiment, the exhaust pipe 222 serving as an exhaust pipe configured to exhaust the gas from the process chamber 201 is constituted by: the source gas exhaust pipe portion 222c through which the source gas flows; the reactive gas exhaust pipe portion 222d through which the reactive gas flows; and the confluent portion 222e where the source gas exhaust pipe portion 222c and the reactive gas exhaust pipe portion 222d join.

The vacuum pump 224 is provided at the exhaust pipe 222 at a downstream side of the confluent portion 222e of the exhaust pipe 222. The vacuum pump 224 is configured to exhaust the inner atmosphere (in particular, the source gas and the reactive gas) of the process chamber 201 via the exhaust pipe 222. As described above, since the vacuum pump 224 is located downstream of the confluent portion 222e, even when exhausting the source gas and the reactive gas from the process chamber 201, it is possible to exhaust the source gas and the reactive gas by using only the vacuum pump 224 without using separate pumps configured to exhaust the source gas and the reactive gas, respectively.

According to a configuration of the substrate processing apparatus 100b, the source gas and the reactive gas are simultaneously supplied to the process chamber 201. Although exhaust ports corresponding to the source gas and the reactive gas are separately provided, the source gas exhaust pipe portion 222c and the reactive gas exhaust pipe portion 222d communicating with the exhaust ports, respectively, join at the confluent portion 222e provided downstream of each of the source gas exhaust pipe portion 222c and the reactive gas exhaust pipe portion 222d. Therefore, at the confluent portion 222e, the source gas and the reactive gas react with each other, whereby the substances such as the by-products may easily be attached to and be deposited on the confluent portion 222e. That is, according to the fourth embodiment, the confluent portion 222e may also be referred to as a “deposition risky portion 222e”. In addition, in order to avoid the deposition of the substances such as the by-products, the confluent portion 222e may not be provided. That is, the source gas and the reactive gas may be exhausted by using separate pumps configured to exhaust the source gas and the reactive gas, respectively. In this case, since a pump configured to exhaust the source gas and another pump configured to exhaust the reactive gas are required instead of the vacuum pump 224, the configuration of the substrate processing apparatus 100b becomes complicated, and the cost of the substrate processing apparatus 100b increases. Therefore, it is not preferable to exhaust the source gas and the reactive gas in a separate manner.

Therefore, since according the substrate processing apparatus 100b of the fourth embodiment the confluent portion 222e is defined as the deposition risky portion 222e (that is, the deposition risky portion 222e is located at the confluent portion 222e), an exhaust pipe gas supply pipe (also referred to as a “fourth supply pipe”) 249i is connected to the confluent portion 222e. An exhaust pipe cleaning contribution gas supply source (also simply referred to as an “exhaust pipe gas supply source”) 249j, an WC 249k and a valve 249l are provided at the exhaust pipe gas supply pipe 249i in the sequential order from an upstream side to a downstream side of the exhaust pipe gas supply pipe 249i. The cleaning contribution gas is supplied into the exhaust pipe 222 via the exhaust pipe gas supply pipe 249i provided with the MFC 249k and the valve 249l.

Similar to the first embodiment, for example, the cleaning gas is used as the cleaning contribution gas supplied to the confluent portion (deposition risky portion) 222e through the exhaust pipe gas supply pipe 249i. However, the fourth embodiment is not limited thereto. For example, similar to the second embodiment, the cleaning auxiliary gas may be used as the cleaning contribution gas.

Subsequently, the cleaning step of the exhaust pipe 222 performed by the substrate processing apparatus 100b of the fourth embodiment will be described. In the fourth embodiment, the cleaning step of the exhaust pipe 222 will be described by way of an example in which the cleaning gas is used as the cleaning contribution gas.

Similar to the first embodiment, according to the fourth embodiment, the cleaning step of the process chamber 201 is performed. After the cleaning step of the process chamber 201 is performed, the cleaning step of the exhaust pipe 222 according to the fourth embodiment is performed.

In the cleaning step of the exhaust pipe 222 according to the fourth embodiment, the valve 2491 is opened. Thereby, the cleaning gas serving as the cleaning contribution gas is supplied to the confluent portion (deposition risky portion) 222e in the exhaust pipe 222 from the exhaust pipe gas supply source 249j through the exhaust pipe gas supply pipe 249i. As a result, the cleaning gas supplied to the deposition risky portion 222e removes the attached substances such as the reaction by-products at the deposition risky portion 222e.

While the fourth embodiment is described by way of an example in which the cleaning gas is supplied in order to remove the attached substances such as the by-products at the confluent portion (deposition risky portion) 222e in the exhaust pipe 222, the fourth embodiment is not limited thereto. For example, similar to the second embodiment, the cleaning auxiliary gas may be used.

While the fourth embodiment is described by way of an example in which the cleaning step of the exhaust pipe 222 includes only a cleaning process of cleaning the deposition risky portion 222e, the fourth embodiment is not limited thereto. For example, the cleaning step of the exhaust pipe 222 may further include at least one among the cleaning process of cleaning the portion between the exhaust port 221 and the APC valve 223 and the cleaning process of cleaning the portion immediately after the downstream side of the APC valve 223.

According to the fourth embodiment described above, it is possible to provide the following effect in addition to the effects (a) through (g) of the first embodiment, the second embodiment or the third embodiment described above.

(h) According to the fourth embodiment, the deposition risky portion 222b of the exhaust pipe 222 is located at the confluent portion 222e where the source gas exhaust pipe portion 222c and the reactive gas exhaust pipe portion 222d join. At the confluent portion 222e, the source gas and the reactive gas react with each other, whereby the substances such as the by-products may easily be attached to and be deposited on the confluent portion 222e. Particularly, the exhaust pipe gas supply pipe 249i is connected to the portion where the reaction by-products are likely to be deposited. Therefore, it is possible to more effectively and efficiently suppress the deposition of the reaction by-products in the exhaust pipe 222.

### Other Embodiments

While the technique is described in detail by way of the above-described embodiments, the above-described technique is not limited thereto. The above-described technique may be modified in various ways without departing from the gist thereof.

For example, in the first embodiment and the second embodiment, when the cleaning contribution gas is supplied to the deposition risky portion 222a in the exhaust pipe 222 (that is, the portion between the exhaust port 221 and the APC valve 223), the APC valve 223 may be fully closed so that the cleaning contribution gas is sealed in deposition risky portion 222a. By completely closing the APC valve 223, the concentration of the cleaning gas at the deposition risky portion 222a increases. Therefore, it is possible to effectively improve a cleaning efficiency.

For example, the above-described embodiments are described by way of an example in which the SiN film is formed on the wafer 200 by alternately supplying the DCS gas serving as the source gas (first gas) and the NH₃ gas serving as the reactive gas (second gas). However, the above-described technique is not limited thereto. For example, the process gases used in the film-forming process are not limited to the DCS gas and the NH₃ gas. That is, the above-described technique may also be applied to film-forming processes wherein other gases are used to form different films, or three or more different process gases are alternately supplied to form a film.

For example, the second embodiment is described by way of an example in which the SiN film serving as a nitride film is formed on the wafer 200 by using the gas such as the NF₃ gas and the F₂ gas as the cleaning gas and using the gas such as the NO gas and the O₂ gas as the cleaning auxiliary gas. However, the above-described technique is not limited thereto. For example, when an oxide film such as a silicon oxide film (also referred to as an “SiO film”) is formed on the wafer 200, hydrogen fluoride (HF) may be used as the cleaning gas and water vapor (H₂O) or alcohol may be used as the cleaning auxiliary gas. When the HF and the H₂O are supplied, the HF and the H₂O may be supplied alternately (that is, the HF and the H₂O are supplied using a cyclic supply process). When the HF and the H₂O are mixed, the corrosiveness increases. Therefore, in order to prevent the HF and the H₂O from mixing, the HF and the H₂are separated by the cyclic supply process.

According to some embodiments in the present disclosure, it is possible to suppress the deposition of the reaction by-products in the exhaust pipe.

1. A substrate processing apparatus comprising:
a process chamber where a substrate is processed;
a source gas supply system, a reactive gas supply system and a purge gas supply system, each of which is configured to supply a process gas into the process chamber;
a process space cleaning gas supply system connected to a process space cleaning gas supply source at an upstream portion thereof and configured to supply a cleaning gas into the process chamber;
an exhaust pipe configured to perform gas exhaust from the process chamber;
an exhaust pipe gas supply system connected to a cleaning auxiliary gas supply source at an upstream portion thereof, wherein a cleaning auxiliary gas is of a different kind from the cleaning gas and is configured to activate the cleaning gas, and connected to a predetermined deposition risky portion in the exhaust pipe at a downstream portion of the exhaust pipe gas supply system, the exhaust pipe gas supply system configured to supply the cleaning auxiliary gas to the deposition risky portion; and
a controller configured to control gas supply through each of the source gas supply system, the reactive gas supply system, the purge gas supply system, the process space cleaning gas supply system and the exhaust pipe gas supply system.,
wherein the exhaust pipe comprises: a source gas exhaust pipe portion through which a source gas serving as one of the process gas flows; and a reactive gas exhaust pipe portion through which a reactive gas serving as another of the process gas flows, and
each of the source gas exhaust pipe portion and the reactive gas exhaust pipe portion is directly connected to the process chamber.

2.-10. (canceled)

11. The substrate processing apparatus of claim 1, wherein the controller is further configured to control the exhaust pipe gas supply system to supply the cleaning auxiliary gas serving as a cleaning contribution gas to the deposition risky portion by opening a cleaning auxiliary gas valve while the gas supply to the process chamber is performed by the process space cleaning gas supply system.

12. The substrate processing apparatus of claim 11, further comprising an exhaust pipe valve provided at the exhaust pipe,
wherein the exhaust pipe valve is closed when the cleaning auxiliary gas is supplied through the exhaust pipe gas supply system.

13. The substrate processing apparatus of claim 11, further comprising an exhaust pipe valve provided at the exhaust pipe,
wherein the deposition risky portion is located downstream of the exhaust pipe valve provided at the exhaust pipe.

14. The substrate processing apparatus of claim 11, further comprising an exhaust pipe valve provided at the exhaust pipe,
wherein the deposition risky portion is located between the process chamber and the exhaust pipe valve provided at the exhaust pipe.

15. (canceled)

16. The substrate processing apparatus of claim 11, wherein the cleaning gas comprises a hydrogen fluoride gas, and the cleaning auxiliary gas comprises water vapor or alcohol.

17. The substrate processing apparatus of claim 1, further comprising an exhaust pipe valve provided at the exhaust pipe,
wherein the exhaust pipe valve is closed when the cleaning auxiliary gas is supplied through the exhaust pipe gas supply system.

18. The substrate processing apparatus of claim 1, wherein the deposition risky portion is located downstream of an exhaust pipe valve provided at the exhaust pipe.

19. The substrate processing apparatus of claim 1, wherein the deposition risky portion is located between the process chamber and an exhaust pipe valve provided at the exhaust pipe.

20. The substrate processing apparatus of claim 1, wherein the exhaust pipe further comprises:
a confluent portion where the source gas exhaust pipe portion and the reactive gas exhaust pipe portion join,
wherein the deposition risky portion is located at the confluent portion.
